(19) United States
(12) Patent Application Publication
(10) Pub. No.: US 2025/0075324 A1
(43) Pub. Date: Mar. 6, 2025

(54) TRIPLE-ELECTRODE DEVICE FOR FUSING AND MIXING DEVICE OF MIXED GAS/SEPARATED GAS

(71) Applicant: JEHARA CORPORATION, Suwon-si (KR)

(72) Inventor: Hongseub KIM, Hwaseong-si (KR)

(73) Assignee: JEHARA CORPORATION, Suwon-si (KR)

(21) Appl. No.: 18/770,293

(22) Filed: Jul. 11, 2024

(30) Foreign Application Priority Data
Sep. 4, 2023 (KR) 10-2023-0117117

(51) Int. Cl. C23C 16/505; C23C 16/455

(52) U.S. Cl. CPC C23C 16/505; C23C 16/45559; C23C 16/45565

(57) ABSTRACT

A triple-electrode device for a fusing and mixing device of mixed gas/separated gas is proposed. The device includes an electrode cover to which RF power is applied, a first shower head unit provided with the electrode cover at an upper part thereof, provided with a first gas supply section into which a first gas is introduced, and provided with a plurality of nozzle stems protruding from a lower part thereof through which the first gas diffused in the first gas supply section is exhausted, and a second shower head unit coupled to the lower part of the first shower head unit, provided with a second gas supply section into which a second gas is introduced, and formed with through holes into which the nozzle stems are respectively inserted and a plurality of exhaust holes through which the second gas diffused in the second gas supply section is exhausted.

### CROSS REFERENCE TO RELATED APPLICATION

The present application claims priority to Korean Patent Application No. 10-2023-0117117, filed Sep. 4, 2023, the entire contents of which are incorporated herein for all purposes by this reference.

### BACKGROUND OF THE INVENTION

### Field of the Invention

The present disclosure relates to a triple-electrode device capable of providing a fusing and mixing device for mixed gas/separated gas in a device for processing using plasma, such as a PECVD process or a PEALD process.

### Description of the Related Art

A Plasma Enhanced Chemical Vapor Deposition (PECVD) device is a device capable of inducing a reaction (i.e., deposition) on a wafer surface at a higher temperature than that in existing CVD processes by using energy within plasma.

A Plasma-Enhanced Atomic Layer Deposition (PEALD) device is capable of forming a thin film by using an electromagnetic field and plasma to repeatedly deposit atomic layers on a solid surface, and is a device capable of generating a very thin film in a nanometer scale.

PECVD and PEALD are deposition methods using plasma and are widely used in the semiconductor and display manufacturing processes. Specifically, PECVD is a method of dissociating and using mixed gases, and PEALD is a method of deposition by using separated precursors and reactive gases.

As such, PECVD and PEALD have deposition methods different from each other, so they are designed and manufactured as devices having different electrodes and shower head structures, and thus these deposition methods require a significant cost and a verification process.

### Documents of Related Art

Korea Patent Application Publication No. 10-2005-0116230 (publication date: Dec. 12, 2005)

Korea Patent Application Publication No. 10-2006-0076714 (publication date: Jul. 4, 2006)

### SUMMARY OF THE INVENTION

An objective of the present disclosure is to provide a triple-electrode device capable of providing a fusing and mixing device for mixed gas/separated gas in a device for processing using plasma, such as a PECVD process or a PEALD process.

According to one form of the present disclosure to achieve such an objective, there is provided a triple-electrode device, including: an electrode cover to which RF power is applied; a first shower head unit provided with the electrode cover at an upper part thereof, provided with a first gas supply section into which a first gas is introduced, and provided with a plurality of nozzle stems protruding from a lower part thereof through which the first gas diffused in the first gas supply section is exhausted; and a second shower head unit coupled to the lower part of the first shower head unit, provided with a second gas supply section into which a second gas is introduced, and formed with through holes into which the nozzle stems are respectively inserted and a plurality of exhaust holes through which the second gas diffused in the second gas supply section is exhausted, wherein the triple-electrode device further includes a third shower head unit capable of being selectively assembled to a lower part of the second shower head unit and allowing the first gas and the second gas to be mixed and then exhausted.

Preferably, the second shower head unit may include an engagement unit into which the third shower head unit is fitted and fixed along an outer circumferential edge thereof.

Preferably, the electrode cover may include: a first gas supply port through which the first gas is injected; a second gas supply port through which the second gas is injected; and a first baffle for diffusing the first gas injected through the first gas supply port to the first gas supply section.

More preferably, the first gas supply port may be a contact point to which the RF power is applied.

More preferably, the first baffle may be provided at a center of the electrode cover.

Preferably, the first shower head unit may further include a second baffle for diffusing the second gas supplied through the second gas supply port to the second gas supply section.

More preferably, the second baffle may be provided at a center of the first shower head unit.

Next, according to the present disclosure, there is provided a substrate processing method, comprising performing deposition or etching by mixed gas of a first gas and a second gas by using the triple-electrode device described above.

In addition, according to the present disclosure, there is provided a substrate processing method, comprising performing deposition or etching by separated gas of a first gas and a second gas by using the triple-electrode device described above.

The triple-electrode device of the present disclosure includes: an electrode cover to which RF power is applied; a first shower head unit provided with the electrode cover at an upper part thereof, provided with a first gas supply section into which a first gas is introduced, and provided with a plurality of nozzle stems protruding from a lower part thereof through which the first gas diffused in the first gas supply section is exhausted; and a second shower head unit coupled to the lower part of the first shower head unit, provided with a second gas supply section into which a second gas is introduced, and formed with through holes into which the nozzle stems are respectively inserted and a plurality of exhaust holes through which the second gas diffused in the second gas supply section is exhausted, wherein the triple-electrode device further includes a third shower head unit capable of being selectively assembled to a lower part of the second shower head unit and allowing the first gas and the second gas to be mixed and then exhausted, whereby there is an effect that a PECVD device and a PEALD device, which were designed and manufactured separately in the related art, may be fused and be provided as one device.

### BRIEF DESCRIPTION OF THE DRAWINGS

FIG. 1 is a configuration diagram illustrating a PECVD device including a triple-electrode device according to an exemplary embodiment of the present disclosure.

FIG. 2 is an exploded configuration diagram illustrating the triple-electrode device according to the exemplary embodiment of the present disclosure.

FIGS. 3A and 3B are bottom views respectively illustrating a first shower head unit and a second shower head unit in the triple-electrode device according to the exemplary embodiment of the present disclosure.

FIG. 4 is a configuration diagram illustrating a PEALD device including the triple-electrode device according to the exemplary embodiment of the present disclosure.

FIG. 5 is a view of graphs illustrating gas supply flows in the PEALD device including the triple-electrode device according to the exemplary embodiment of the present disclosure.

### DETAILED DESCRIPTION OF THE INVENTION

Specific structures and functional descriptions presented in the present exemplary embodiment of the present disclosure are exemplified for the purpose of describing the exemplary embodiment according to a concept of the present disclosure only, and exemplary embodiments according to the concept of the present disclosure may be implemented in various forms. In addition, it should not be construed as being limited to the exemplary embodiments described herein, and should be understood to include all modifications, equivalents, and substitutes included in the idea and technical scope of the embodiment of the present disclosure.

Meanwhile, in the embodiment of the present disclosure, although the terms “first”, “second”, etc. may be used herein to describe various components, these components should not be limited by these terms. The terms are only used for the purpose of distinguishing one component from other components. For instance, within a scope not departing from the scope of rights according to the concept of the embodiment of the present disclosure, a first component may be referred to as a second component, and similarly, the second component may also be referred to as the first component.

It will be understood that when a component is referred to as being “coupled” or “connected” to another component, it can be directly coupled or connected to the other component or intervening components may also be present therebetween. In contrast, when a component is described as being “directly connected”, “directly coupled”, or “directly linked” to another component, it should be understood that there are no intervening components present therebetween. Other expressions for describing the relationship between components, such as “between”, “directly between”, “adjacent to”, or “directly adjacent to” should also be construed in the same way.

The terminology used in the present specification is for the purpose of merely describing particular exemplary embodiment, and is not intended to be limiting. As used herein, the singular forms are intended to include the plural forms as well, unless the context clearly indicates otherwise. In the present specification, it will be understood that the terms “comprise”, “include”, “have”, and the like specify the presence of embodied features, numbers, steps, operations, elements, components, and/or combinations thereof, but do not exclude in advance the presence or addition of one or more other features, numbers, steps, operations, elements, components, and/or combinations thereof.

Hereinafter, a specific exemplary embodiment of the present disclosure will be described with reference to the attached drawings.

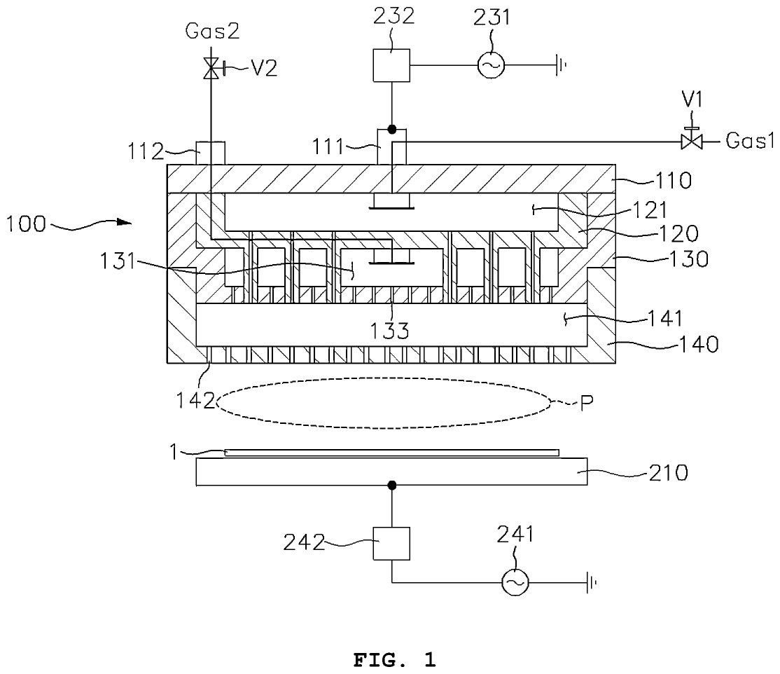

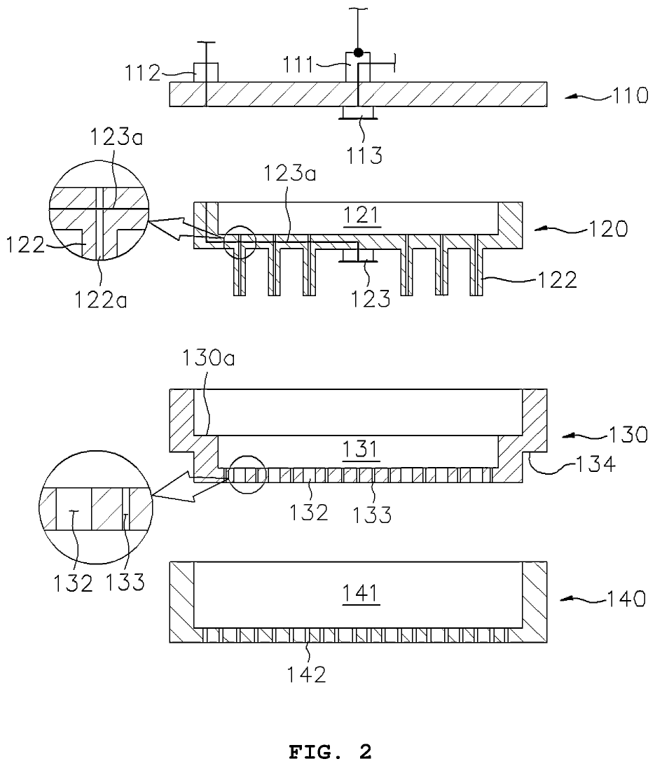

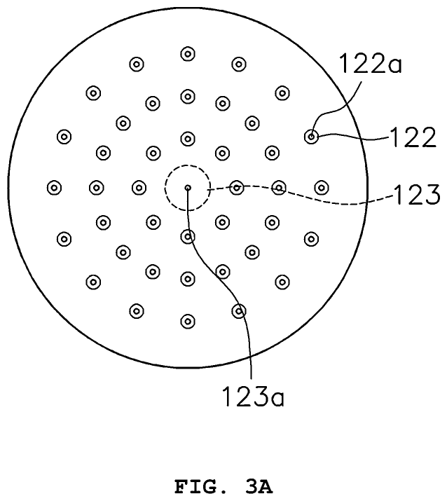

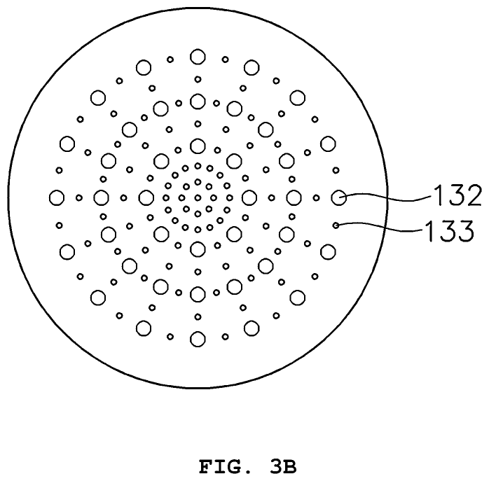

FIG. 1 is a configuration diagram illustrating a PECVD device including a triple-electrode device according to an exemplary embodiment of the present disclosure. FIG. 2 is an exploded configuration diagram illustrating the PECVD device including the triple-electrode device according to the exemplary embodiment of the FIGS. 3A and 3B are bottom views respectively present disclosure. illustrating a first shower head unit and a second shower head unit in the triple-electrode device according to the exemplary embodiment of the present disclosure.

Referring to FIGS. 1 to 3, a triple-electrode device 100 according to the present exemplary embodiment includes an electrode cover 110, a first shower head unit 120, and a second shower head unit 130, and depending on the process mode (i.e., PECVD or PEALD), includes a third shower head unit 140 selectively assembled to the second shower head unit 130.

The electrode cover 110 is a circular conductive plate to which RF power is applied, and may include: a first gas supply port 111 through which a first gas is injected; a second gas supply port 112 through which a second gas is injected; and a first baffle 113 for diffusing the first gas injected through the first gas supply port 111 to a first gas supply section 121. The gas supply ports 111 and 112 are respectively provided with supply control valves V1 and V2 for controlling the flow rates of the first gas and second gas. Preferably, the first baffle 113 is provided at the center of the electrode cover 110.

Preferably, the first gas supply port 111 is a power contact point connected to an RF power supply unit 231 to which RF power is applied. The RF power supply unit 231 may be connected to the first gas supply port 111 through an impedance matching unit 232 interposed therebetween.

The first shower head unit 120 is provided with an electrode cover 110 at an upper part thereof, is provided with a first gas supply section 121 into which the first gas is introduced, and is provided with a plurality of nozzle stems 122 formed protruding and through which the first gas diffused in the first gas supply section 121 is exhausted. Each nozzle stem 122 has a nozzle hole 122a formed therethrough. Preferably, in a state in which the first shower head unit 120 and the second shower head unit 130 are assembled, the length of each nozzle stem 122 is determined appropriately, so that a lower tip of each nozzle stem 122 is positioned on a bottom surface of the second shower head unit 130.

The first shower head unit 120 may include a second baffle 123 for diffusing the second gas supplied through the second gas supply port 112. Preferably, the second baffle 123 is provided at the center of the first shower head unit 120.

The second shower head unit 130 is coupled to the lower part of the first shower head unit 120, is provided with a second gas supply section 131 into which a second gas is introduced, and is formed with through holes 132 into which the nozzle stems 122 are respectively inserted and a plurality of exhaust holes 133 through which the second gas diffused in the second gas supply section 131 is exhausted.

Meanwhile, the second shower head unit 130 is provided with a stepped part 130a on an inner circumferential surface thereof so that the first shower head unit 120 having a predetermined level difference is inserted to the inner side of the second shower head unit 130, thereby providing a second gas supply section 131 between the first shower head unit 120 and the second shower head unit 130. Preferably, outer diameters of the electrode cover 110 and the second shower head unit 130 are provided to be the same.

The second shower head unit 130 includes an engagement unit 134 at a lower part thereof into which a third shower head unit 140 is fittable and fixable. In the present exemplary embodiment, the engagement unit 134 is provided with a step 134 formed around a lower outer circumferential surface of the second shower head unit 130, so that a third shower head unit 140 is fitted and assembled so as to be inserted to the outer side of a lower part of the second shower head unit 130.

The third shower head unit 140 is capable of being selectively assembled to the lower part of the second shower head unit 130, thereby providing a mixing gas supply section 141 in which a first gas and a second gas are mixed and forming each mixing gas supply nozzle 142 through which the mixed gas of the mixing gas supply section 141 is exhausted.

In correspondence with such a triple-electrode device 100, a bias electrode 210 on which a substrate (i.e., a wafer or glass) 1 is seated is provided at a lower part thereof. The bias electrode 130 is provided with a bias impedance matching unit 232 and is connected to a bias RF power supply unit 241.

In the PECVD device configured in this way, in the PECVD mode, the first gas is introduced into the first gas supply section 121 of the first shower head unit 120, the second gas is introduced into the second gas supply section 131 of the second shower head unit 130, and then these gases are mixed in the mixing gas supply section 141 of the third shower head unit 140, so as to be uniformly supplied to a reaction chamber, whereby the mixed gas supplied is dissociated by plasma and then the deposition (or etching) process of the substrate 1 is performed in the mixed gas (PECVD) mode.

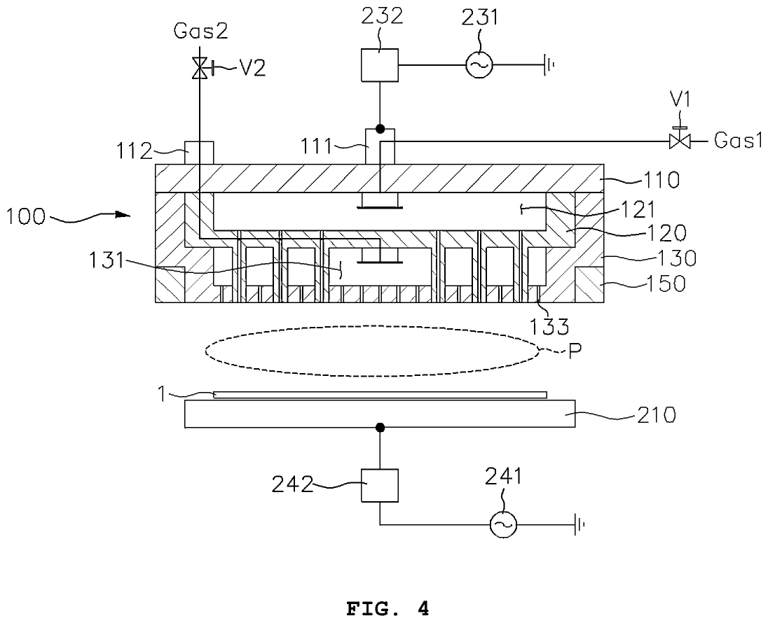

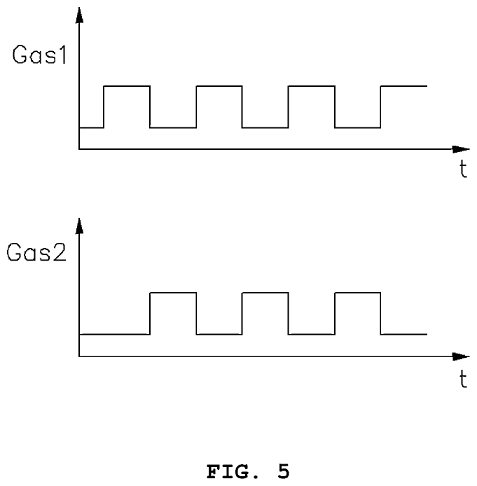

FIG. 4 is a configuration diagram illustrating a PEALD device including the triple-electrode device according to the exemplary embodiment of the present disclosure. FIG. 5 is a view of graphs illustrating gas supply flows in the PEALD device including the triple-electrode device according to the exemplary embodiment of the present disclosure. The same components as those in the previous exemplary embodiments will use the same symbols, so overlapping descriptions will be omitted.

Referring to FIG. 4, the triple-electrode device 100 according to the exemplary embodiment of the present disclosure is for the PEALD process, is the same as the previous exemplary embodiment in terms of including the electrode cover 110, the first shower head unit 120, and the second shower head unit, and is configured to include a rim block 150 instead of the third shower head unit for providing the mixing gas supply section.

The rim block 150 is fitted and fixed to the engagement unit 134 (see FIG. 2) of the second shower head unit 130.

The PEALD device configured in this way controls a first supply control valve V1 and a second supply control valve V2 in the PEALD mode to separately supply a first gas and a second gas according to time (see FIG. 4). The first gas and the second gas may respectively be supplied directly to a reaction chamber through the first shower head unit 120 and the second shower head unit 130, and the deposition (or etching) of the substrate 1 is performed by plasma by using the first gas and second gas supplied.

As described above, the triple-electrode device of the present disclosure has an effect that a PECVD device and a PEALD device, which were designed and manufactured separately in the related art, may be fused and be provided as one device.

The present disclosure described above is not limited by the above-described exemplary embodiments and the accompanying drawings, and obviously, those skilled in the art will appreciate that various substitutions, modifications, and changes are possible within the scope of the technical spirit of the present disclosure.

What is claimed is:

1. A triple-electrode device, comprising:
an electrode cover to which RF power is applied;
a first shower head unit provided with the electrode cover at an upper part thereof, provided with a first gas supply section into which a first gas is introduced, and provided with a plurality of nozzle stems protruding from a lower part thereof through which the first gas diffused in the first gas supply section is exhausted; and
a second shower head unit coupled to the lower part of the first shower head unit, provided with a second gas supply section into which a second gas is introduced, and formed with through holes into which the nozzle stems are respectively inserted and a plurality of exhaust holes through which the second gas diffused in the second gas supply section is exhausted,
wherein the triple-electrode device further comprises:
a third shower head unit capable of being selectively assembled to a lower part of the second shower head unit and allowing the first gas and the second gas to be mixed and then exhausted.

2. The triple-electrode device of claim 1, wherein the second shower head unit comprises:
an engagement unit into which the third shower head unit is fitted and fixed along an outer circumferential edge thereof.

3. The triple-electrode device of claim 1, wherein the electrode cover comprises:
a first gas supply port through which the first gas is injected;
a second gas supply port through which the second gas is injected; and
a first baffle for diffusing the first gas injected through the first gas supply port to the first gas supply section.

4. The triple-electrode device of claim 3, wherein the first gas supply port is a contact point to which the RF power is applied.

5. The triple-electrode device of claim 4, wherein the first baffle is provided at a center of the electrode cover.

6. The triple-electrode device of claim 3, wherein the first shower head unit further comprises:
a second baffle for diffusing the second gas supplied through the second gas supply port to the second gas supply section.

7. The triple-electrode device of claim 6, wherein the second baffle is provided at a center of the first shower head unit.

8. A substrate processing method, comprising performing deposition or etching by mixed gas of a first gas and a second gas by using the triple-electrode device of claim 1.

9. A substrate processing method, comprising performing deposition or etching by separated gas of a first gas and a second gas by using the triple-electrode device of claim 1.
